(19) United States
(12) Patent Application Publication
(10) Pub. No.: US 2008/0130958 A1
(43) Pub. Date: Jun. 5, 2008

(54) METHOD AND SYSTEM FOR VISION-BASED PARAMETER ADJUSTMENT

(75) Inventor: Thomas J. Ziomek, Algonquin, IL (US)

Correspondence Address: MOTOROLA, INC., 1303 EAST ALGONQUIN ROAD, IL01/3RD, SCHAUMBURG, IL, 60196, US

(73) Assignee: MOTOROLA, INC., Schaumburg, IL (US)

(21) Appl. No.: 11/565,232

(22) Filed: Nov. 30, 2006

(51) Int. Cl. G06K 9/62; H03G 3/00

(52) U.S. Cl. 382/116; 382/115; 381/107

(57) ABSTRACT

A vision-based parameter adjustment method (40) and system (10) can include a presentation device (14), a camera (18) and a processor 16). The system can visually recognize (41) a user or a set of users using a vision-based recognition system, track (42) at least one user preference setting for the user or the set of users, and automatically set (44) the at least one user preference setting upon visually recognizing the set. The method can determine (43) a time of day and occupancy within a location. The method can modify (45) a pre-set setting for the user or the set of users as an evolving preference. The preset settings can also be modified (46) based on factors selected among time of day, day of the week, channel selection, and environment. The method can also modify (47) a preset setting the set of users based on a trend.

### FIELD

This invention relates parameter adjustments, and more particularly to a method and system for vision-based parameter adjustment.

### BACKGROUND

Users have differing preferences for the volume of audio devices such as an entertainment system or car radio. As individuals take turns using such a device, each has to adjust the volume to their liking, or manually program a “preset” volume for their use. Furthermore, any time there are multiple simultaneous users a mutually acceptable volume is typically agreed upon for that specific set of users. Finally, users' volume preferences can change slowly over time, necessitating another manual programming of a preset. No existing system is known to recognize users in an audience to enable an automatic adjustment of parameters such as volume.

Several known systems have volume presets per channel and optionally have different presets per user, but they do not specify how a device knows or recognizes which user(s) are present and they are not adaptive to environments with multiple users. Furthermore, many systems require each preset (volume level) to be manually configured and they fail to account for multiple listeners.

Other related technologies can include Automatic Volume/Gain Control (AGC) that maintains a fixed output volume in the presence of varying input levels or systems that adjust volume to maintain a constant signal to noise (S/N) ratio relative to ambient noise levels, or based on whether the listener is speaking. Some systems have separate preset levels for speakers as opposed to earphone outputs. Some systems have a mechanism that easily returns a system to a default volume.

### SUMMARY

Embodiments in accordance with the present invention can provide a vision based method and system for adjusting parameters such as volume. Such a method and system is adaptive and can adjust parameters upon recognition of multiple users. Thus, there can be volume presets for not only each individual, but also each set of users. Further, volume presets or other presets can be learned and users are not necessarily required to follow any special process to configure audio equipment with their preferred presets. Presets can also be adaptive by examining trends in a user's or set of users volume preference as they are detected and automatically adopted by the system. Such as system can save a user from having to re-configure the system for one's changing preferences.

In a first embodiment of the present invention, a vision-based parameter adjustment method can include the steps of visually recognizing a user or a set of users using a vision-based recognition system, tracking at least one user preference setting for the user or the set of users, and automatically setting the at least one user preference setting upon visually recognizing the user or the set of users. The user preference or preferences can include volume, equalization, contrast or brightness for example. The method can further include the step of modifying a pre-set setting for the user or the set of users as an evolving preference. The method can further determine a time of day and occupancy within a location and modify a preset setting based on the time of day or the occupancy. The preset settings can also be modified based on factors selected among time of day, day of the week, channel selection, and environment. The method can also modify a preset setting for the user or the set of users based on a trend. The method can use facial recognition or body shape recognition to characterize each member of an audience. The method can also apply passcode settings automatically when the user is alone or when the set of users are all known to have the passcode and withhold application of the passcode when a user or a set of users are unrecognized. The method can also automatically reduce a volume when detecting public safety vehicle lights.

In a second embodiment of the present invention, a system for adjusting a parameter based on visual recognition can include a presentation device having a plurality of settings or parameters, a camera coupled to the presentation device, and a processor coupled to the camera and the presentation device. The processor can be programmed to visually recognize a user or a set of users using a vision-based recognition system, track at least one user preference setting for the user or the set of users, and automatically set the at least one user preference setting upon visually recognizing the user or the set of users. The user preference settings can include volume, equalization, contrast or brightness. The processor can be programmed to modify a pre-set setting for the user or the set of users as an evolving preference and can be further programmed to determine a time of day and occupancy within a location and modify a preset setting based on the time of day or the occupancy. The processor can be programmed to modify a preset setting based on factors selected among time of day, day of the week, channel selection, and environment. The processor can be programmed to modify a preset setting for the user or the set of users base on a trend. The system can use facial recognition or body shape recognition to characterize each member of an audience. The processor can also apply passcode settings automatically when the user is alone or when the set of users are all known to possess the passcode and withholding application of the passcode when a user or a set of users are unrecognized. The processor can be further programmed to automatically reduce a volume when detecting public safety vehicle lights.

In a third embodiment of the present invention, an entertainment system having a system for adjusting a parameter based on visual recognition can include a presentation device having at least one setting or parameter, a camera coupled to the presentation device, and a processor coupled to the camera and the presentation device. The processor can be programmed to visually recognize a user or a set of users using a vision-based recognition system, track at least one user preference setting such as volume setting for the user or the set of users, and automatically set the at least one user preference setting upon visually recognizing the user or the set of users. The processor can be further programmed to modify a preset setting based on factors selected among time of day, day of the week, channel selection, and environment.

The terms “a” or “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The term “coupled,” as used herein, is defined as connected, although not necessarily directly, and not necessarily mechanically.

The terms “program,” “software application,” and the like as used herein, are defined as a sequence of instructions designed for execution on a computer system. A program, computer program, or software application may include a subroutine, a function, a procedure, an object method, an object implementation, an executable application, an applet, a servlet, a midlet, a source code, an object code, a shared library/dynamic load library and/or other sequence of instructions designed for execution on a computer system. The “processor” as described herein can be any suitable component or combination of components, including any suitable hardware or software, that are capable of executing the processes described in relation to the inventive arrangements.

Other embodiments, when configured in accordance with the inventive arrangements disclosed herein, can include a system for performing and a machine readable storage for causing a machine to perform the various processes and methods disclosed herein.

### BRIEF DESCRIPTION OF THE DRAWINGS

FIG. 1 is an illustration of a system of vision-based parameter adjustment in accordance with an embodiment of the present invention.

FIG. 2 is the system of FIG. 1 with several recognized users in accordance with an embodiment of the present invention.

FIG. 3 is an illustration of another system of vision based parameter adjustment in accordance with an embodiment of the present invention.

FIG. 4 is a flow chart of a method of vision-based parameter adjustment in accordance with an embodiment of the present invention.

FIG. 5 is an illustration of a system for vision-based parameter adjustment in accordance with an embodiment of the present invention.

### DETAILED DESCRIPTION OF THE DRAWINGS

While the specification concludes with claims defining the features of embodiments of the invention that are regarded as novel, it is believed that the invention will be better understood from a consideration of the following description in conjunction with the figures, in which like reference numerals are carried forward.

Embodiments herein can be implemented in a wide variety of exemplary ways that can enable a system to continually monitor its audience using facial recognition or other means to characterize each member of the audience and optionally other environmental factors. Over time, such a system can learn its regular users. For each audience or set of users the system can also keep track of audio volume setting (or other settings) the audience has used the last several times. The system uses such information to determine an initial audio volume (or other preset parameter or setting) to use the next time that such audience appears before the system.

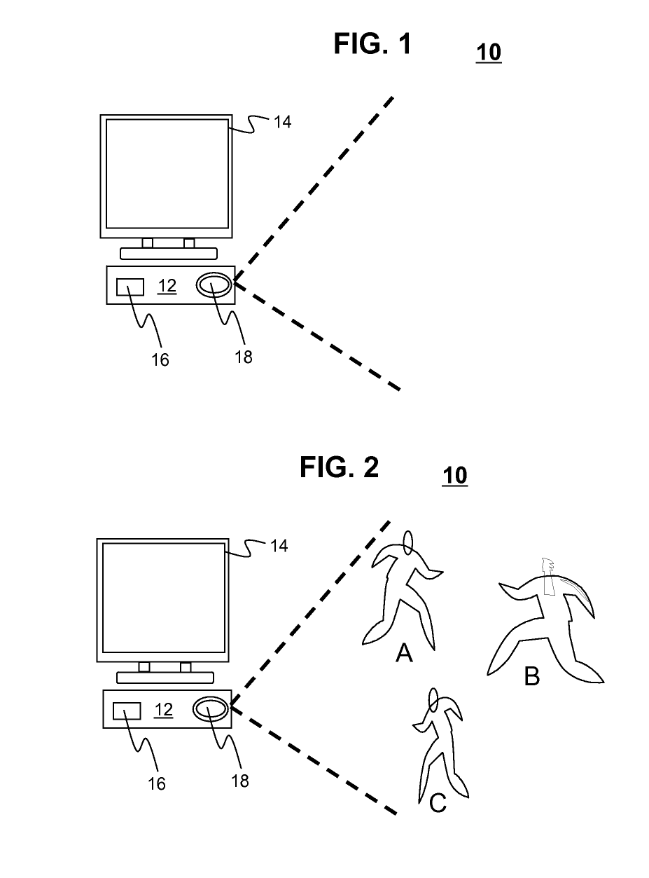

Referring to FIG. 1, a system 10 can include a home entertainment device 12 such as a digital set-top box coupled to a presentation device 14 such as a display. The system can further include a processor 16 and a camera 18 used for vision recognition. Since no one is in the line of sight of the camera 18 in FIG. 1, the system can likely maintain a default setting. In FIG. 2, the system can visually recognize three users, A, B, and C possibly using facial recognition or shape recognition. The system can have a record of each user's parameter preference individually and can have a combined parameter preference when all three are in an audience. In one embodiment, the system can determine an average or mean parameter setting for the three users and automatically set the system to such setting upon recognition of such audience. For example, A can have a volume preference setting of 5.2, B of 3.8, and C of 6.5. If A and B are only in the audience, then the automatic setting might be set to 4.5. If A, B, and C are all in the audience, then the automatic setting might be 5.2. In another embodiment, the system can record an actual setting used when such audience is present and maintain this in memory for use when the same audience is present and recognized in the future. For example, if A and B are recognized as an audience and a setting of 3.9 was previously used, then the system will use 3.9 as a default setting the next time A and B are recognized as the audience members. Likewise, if A, B, and C are recognized as an audience and a setting of 4.1 was previously used, then the system will use 4.1 as a default setting the next time A, B, and C are recognized as the audience members.

An entertainment or other audio system can include computer vision, specifically of its audience. It can remember who it sees in its audience over time and is able to recognize who appears multiple times (or at least somewhat often). For each distinct set of users (1, or more), it can remember the volume setting(s) or other settings selected by that audience and uses that information to determine a preferred volume preset or other preset for that audience. The next time a given user set appears before the device, it automatically applies that preset applicable to the user set. If a user [set] tends to consistently change the volume from its preset, the system can correspondingly modify its preset for that user set to better match its evolving preference. The system can optionally take into account other factors that can include time of day (morning vs. mid-day vs. evening), weekday vs. weekend, what particular channel/station is selected, windows open or closed, among other factors to more finely determine the likely preferred volume for a given situation.

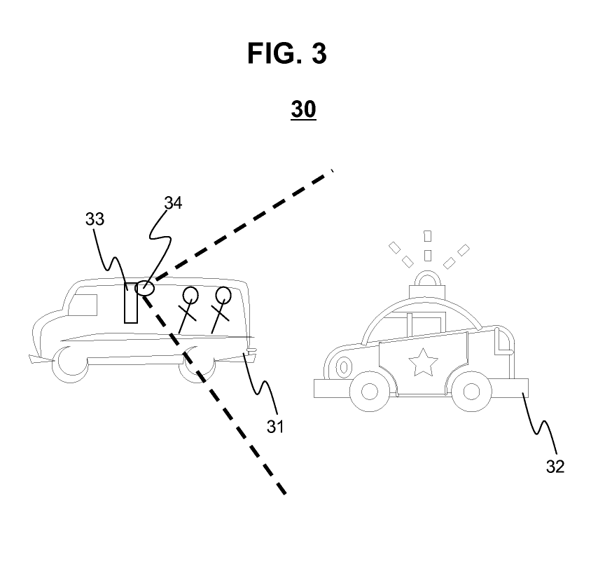

Home entertainment systems, stereos, TVs, set-top boxes and other similar devices are most likely to apply this. It could also be applied to automotive entertainment systems, and to non-entertainment audio systems such as baby monitors, and marine sonar systems. For example, referring to FIG. 3, an automotive entertainment system 30 can include a presentation device 33 in a car or van 31 that further includes a camera or computer vision system 34. This system can operate much like the system 10 described above. Additionally, such a system can monitor for other environmental factors more particular to a vehicular setting. For example, system 30 can monitor for public safety vehicle lights coming from a fire truck, paramedic truck or police car 32 for example. In such instances, the detection of safety vehicle lights can cause the presentation device to mute, blank-out, give additional warning or perform other functions as needed.

Over time, consumers expect their everyday devices to become more attentive to their individual preferences (e.g., cars adjust seats, pedals and mirrors to the driver, PCs have many per-user settings, personal video recorders (PVRs) “learn” what sorts of shows are desired). But, consumers typically find it difficult and/or bothersome to have to configure a device with their preferences. Changing such preset preferences is also problematic.

As noted above, most home entertainment systems have several audiences (different sets of users) and different audiences prefer different audio volumes which can be significant. A system can conveniently automatically adjust its volume or other settings to the current audience's preference. This can be useful when the last user of the system left the settings at an exceptionally loud volume. An automatic system avoids manual steps and procedures and can be transparent to further avoid the use of RFID tags, or voice commands. Such a system can be flexible in that it can accommodate a large number of users and combinations of users. Such a system can be adaptive so that if an audience's preference changes over time, such change is automatically reflected by the system's behavior.

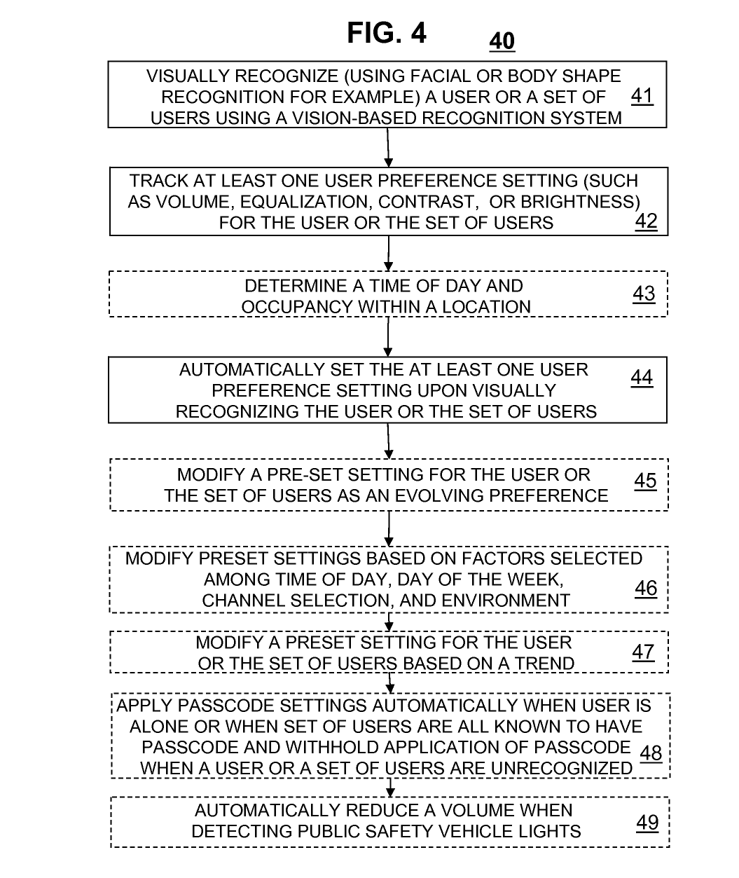

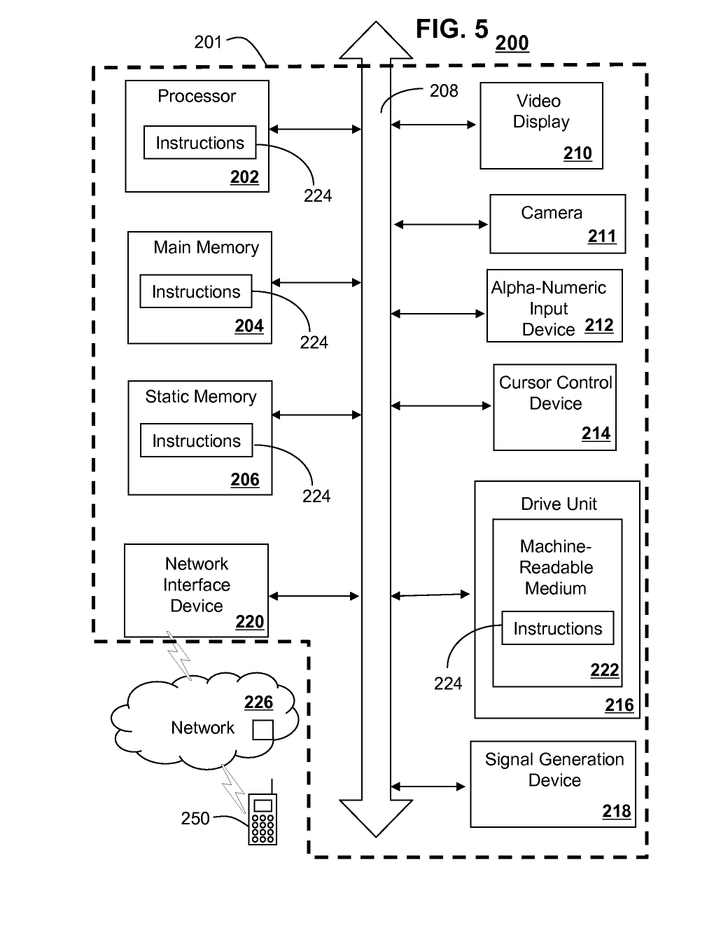

Referring to FIG. 4, a flow chart illustrating a vision-based parameter adjustment method 40 can include the step 41 of visually recognizing a user or a set of users using a vision-based recognition system, tracking at least one user preference setting for the user or the set of users at step 42, and automatically setting the at least one user preference setting upon visually recognizing the user or the set of users at step 44. The method 40 can further determine a time of day and occupancy within a location at step 43 and modify a preset setting based on the time of day or the occupancy. The user preference or preferences can include volume, equalization, contrast or brightness for example. The method 40 can further include the step 45 of modifying a pre-set setting for the user or the set of users as an evolving preference. The preset settings can also be modified based on factors selected among time of day, day of the week, channel selection, and environment at step 46. The method 40 can also modify a preset setting for the user or the set of users based on a trend at step 47. The method can use facial recognition or body shape recognition to characterize each member of an audience. The method 40 can also apply passcode settings automatically when the user is alone or when the set of users are all known to have the passcode and withhold application of the passcode when a user or a set of users are unrecognized at step 48. The method can also optionally automatically reduce a volume when detecting public safety vehicle lights at step 49.

There are numerous extensions to the concepts present herein. For example, in one embodiment, the system can recognize the presence of individuals in a home or residence and accordingly adjust or set parameters. For example, if an individual is the only person in the home, the system will enable such individual to adjust the volume as desired without any threshold limitation, whereas if the system detects other individuals in bed or sleeping, the system can limit adjustments of volume to a much lower threshold. The maximum volume can also be limited base on time of day or day of the week. As noted above, a V-Chip passcode can be tracked. Rather than a parent having to enter their passcode every time, the system can learn or recognize who enters the code and then apply it whenever that person is present, or apply it only when everybody in the audience is known to possess the passcode.

FIG. 5 depicts an exemplary diagrammatic representation of a machine in the form of a computer system 200 within which a set of instructions, when executed, may cause the machine to perform any one or more of the methodologies discussed above. In some embodiments, the machine operates as a standalone device. In some embodiments, the machine may be connected (e.g., using a network) to other machines. In a networked deployment, the machine may operate in the capacity of a server or a client user machine in server-client user network environment, or as a peer machine in a peer-to-peer (or distributed) network environment. For example, the computer system can include a recipient device 201 and a sending device 250 or vice-versa.

The machine may comprise a server computer, a client user computer, a personal computer (PC), a tablet PC, personal digital assistant, a cellular phone, a laptop computer, a desktop computer, a control system, a network router, switch or bridge, or any machine capable of executing a set of instructions (sequential or otherwise) that specify actions to be taken by that machine, not to mention a mobile server. It will be understood that a device of the present disclosure includes broadly any electronic device that provides voice, video or data communication. Further, while a single machine is illustrated, the term “machine” shall also be taken to include any collection of machines that individually or jointly execute a set (or multiple sets) of instructions to perform any one or more of the methodologies discussed herein.

The computer system 200 can include a controller or processor 202 (e.g., a central processing unit (CPU), a graphics processing unit (GPU, or both), a main memory 204 and a static memory 206, which communicate with each other via a bus 208. The computer system 200 may further include a presentation device such as a video display unit 210 (e.g., a liquid crystal display (LCD), a flat panel, a solid state display, or a cathode ray tube (CRT)) and a camera or video sensor 211. The computer system 200 may include an input device 212 (e.g., a keyboard), a cursor control device 214 (e.g., a mouse), a disk drive unit 216, a signal generation device 218 (e.g., a speaker or remote control that can also serve as a presentation device) and a network interface device 220. Of course, in the embodiments disclosed, many of these items are optional.

The disk drive unit 216 may include a machine-readable medium 222 on which is stored one or more sets of instructions (e.g., software 224) embodying any one or more of the methodologies or functions described herein, including those methods illustrated above. The instructions 224 may also reside, completely or at least partially, within the main memory 204, the static memory 206, and/or within the processor 202 during execution thereof by the computer system 200. The main memory 204 and the processor 202 also may constitute machine-readable media.

Dedicated hardware implementations including, but not limited to, application specific integrated circuits, programmable logic arrays and other hardware devices can likewise be constructed to implement the methods described herein. Applications that may include the apparatus and systems of various embodiments broadly include a variety of electronic and computer systems. Some embodiments implement functions in two or more specific interconnected hardware modules or devices with related control and data signals communicated between and through the modules, or as portions of an application-specific integrated circuit. Thus, the example system is applicable to software, firmware, and hardware implementations.

In accordance with various embodiments of the present invention, the methods described herein are intended for operation as software programs running on a computer processor. Furthermore, software implementations can include, but are not limited to, distributed processing or component/object distributed processing, parallel processing, or virtual machine processing can also be constructed to implement the methods described herein. Further note, implementations can also include neural network implementations, and ad hoc or mesh network implementations between communication devices.

The present disclosure contemplates a machine readable medium containing instructions 224, or that which receives and executes instructions 224 from a propagated signal so that a device connected to a network environment 226 can send or receive voice, video or data, and to communicate over the network 226 using the instructions 224. The instructions 224 may further be transmitted or received over a network 226 via the network interface device 220.

While the machine-readable medium 222 is shown in an example embodiment to be a single medium, the term “machine-readable medium” should be taken to include a single medium or multiple media (e.g., a centralized or distributed database, and/or associated caches and servers) that store the one or more sets of instructions. The term “machine-readable medium” shall also be taken to include any medium that is capable of storing, encoding or carrying a set of instructions for execution by the machine and that cause the machine to perform any one or more of the methodologies of the present disclosure. The terms “program,” “software application,” and the like as used herein, are defined as a sequence of instructions designed for execution on a computer system. A program, computer program, or software application may include a subroutine, a function, a procedure, an object method, an object implementation, an executable application, an applet, a servlet, a midlet, a source code, an object code, a shared library/dynamic load library and/or other sequence of instructions designed for execution on a computer system.

In light of the foregoing description, it should be recognized that embodiments in accordance with the present invention can be realized in hardware, software, or a combination of hardware and software. A network or system according to the present invention can be realized in a centralized fashion in one computer system or processor, or in a distributed fashion where different elements are spread across several interconnected computer systems or processors (such as a microprocessor and a DSP). Any kind of computer system, or other apparatus adapted for carrying out the functions described herein, is suited. A typical combination of hardware and software could be a general purpose computer system with a computer program that, when being loaded and executed, controls the computer system such that it carries out the functions described herein.

In light of the foregoing description, it should also be recognized that embodiments in accordance with the present invention can be realized in numerous configurations contemplated to be within the scope and spirit of the claims. Additionally, the description above is intended by way of example only and is not intended to limit the present invention in any way, except as set forth in the following claims.

What is claimed is:

1. A vision-based parameter adjustment method, comprising the steps of:
visually recognizing a user or a set of users using a vision-based recognition system;
tracking at least one user preference setting for the user or the set of users; and
automatically setting the at least one user preference setting upon visually recognizing the user or the set of users.

2. The method of the claim 1, wherein the user preference settings comprise volume, equalization, contrast or brightness.

3. The method of claim 1, wherein the method further comprises the step of modifying a pre-set setting for the user or the set of users as an evolving preference.

4. The method of claim 1, wherein the method further comprises the step of modifying a preset setting based on factors selected among time of day, day of the week, channel selection, and environment.

5. The method of claim 1, wherein the method further comprises the step of modifying a preset setting for the user or the set of users based on a trend.

6. The method of claim 1, wherein the method further uses facial recognition or body shape recognition to characterize each member of an audience.

7. The method of claim 1, wherein the method further comprises the step of determining a time of day and an occupancy within a location and modifying a preset setting based on the time of day or the occupancy.

8. The method of claim 1, wherein the method further comprises the step of applying passcode settings automatically when the user is alone or when the set of users are all known to have the passcode and withholding application of the passcode when a user or a set of users are unrecognized.

9. The method of claim 1, wherein the method further comprises the step of automatically reducing a volume when detecting public safety vehicle lights.

10. A system for adjusting a parameter based on visual recognition, comprising:
a presentation device having a plurality of settings or parameters;
a camera coupled to the presentation device; and
a processor coupled to the camera and the presentation device, wherein the processor is programmed to:
visually recognize a user or a set of users using a vision-based recognition system;
track at least one user preference setting for the user or the set of users; and
automatically set the at least one user preference setting upon visually recognizing the user or the set of users.

11. The system of the claim 10, wherein the user preference settings comprise volume, equalization, contrast or brightness.

12. The system of claim 10, wherein the processor is further programmed to modify a pre-set setting for the user or the set of users as an evolving preference.

13. The system of claim 10, wherein the processor is further programmed to modify a preset setting based on factors selected among time of day, day of the week, channel selection, and environment.

14. The system of claim 10, wherein the processor is further programmed to modify a preset setting for the user or the set of users base on a trend.

15. The system of claim 10, wherein the processor is further programmed to use facial recognition or body shape recognition to characterize each member of an audience.

16. The system of claim 10, wherein the processor is further programmed to determine a time of day and an occupancy within a location and modify a preset setting based on the time of day or the occupancy.

17. The system of claim 10, wherein the processor is further programmed to apply passcode settings automatically when the user is alone or when the set of users are all known to possess the passcode and withholding application of the passcode when a user or a set of users are unrecognized.

18. The system of claim 10, wherein the processor is further programmed to automatically reduce a volume when detecting public safety vehicle lights.

19. An entertainment system having a system for adjusting a parameter based on visual recognition, comprising:
a presentation device having at least one setting or parameter;
a camera coupled to the presentation device; and
a processor coupled to the camera and the presentation device, wherein the processor is programmed to:
visually recognize a user or a set of users using a vision-based recognition system;
track at least one user preference setting for the user or the set of users, wherein the at least one user preference setting comprises a volume setting; and
automatically set the at least one user preference setting upon visually recognizing the user or the set of users.

20. The entertainment system of claim 19, wherein the processor is further programmed to modify a preset setting based on factors selected among time of day, day of the week, channel selection, and environment.
